(19) United States
(12) Patent Application Publication
(10) Pub. No.: US 2025/0366142 A1
(43) Pub. Date: Nov. 27, 2025

(54) METHOD OF FABRICATING TRANSISTOR HAVING EXPANDED GATE STRUCTURE, AND TRANSISTOR FABRICATED THEREBY

(71) Applicants: TAIWAN SEMICONDUCTOR MANUFACTURING COMPANY, LTD, Hsinchu (TW); TSMC NANJING COMPANY, LIMITED, Nanjing (CN)

(72) Inventors: Hang XUE, Hsinchu (TW); I-Chih CHEN, Hisnchu (TW)

(21) Appl. No.: 19/286,967

(22) Filed: Jul. 31, 2025

Related U.S. Application Data
(63) Continuation of application No. 18/598,580, filed on Mar. 7, 2024.

(30) Foreign Application Priority Data
Feb. 26, 2024 (CN) 202410212722.7

(51) Int. Cl. H10D 64/27; H01L 21/768; H10D 64/01

(52) U.S. Cl. CPC H10D 64/513; H01L 21/76877; H10D 64/015; H10D 64/017; H10D 64/018

(57) ABSTRACT

A method of fabricating a transistor includes: forming a dummy gate and gate spacers; forming an ILD layer alongside the gate spacers; forming a trench having a lower portion and an upper portion wider than the lower portion, forming the trench including: removing the dummy gate and part of the gate spacers; forming a gate structure in the trench; and forming a SAC layer in the trench on the gate structure, wherein: the gate structure has a lower portion and a wider upper portion, a first gate spacer has a first inner sidewall that faces a first side of the lower portion, and a second gate spacer has a second inner sidewall that faces a second side of the lower portion, the first inner sidewall being spaced from the second inner sidewall by a first distance, and the self-aligned contact layer is wider than the first distance.

### CROSS REFERENCE TO RELATED APPLICATIONS

This application is a continuation of U.S. patent application Ser. No. 18/598,580, filed Mar. 7, 2024, which claims priority to Chinese Application No. 202410212722.7, filed Feb. 26, 2024, the disclosures of each of which are hereby incorporated by reference in their entireties.

### BACKGROUND

Dimensions of transistors have decreased as process nodes have advanced and integrated circuits have become more dense. The down-scaling of transistors to smaller dimensions allows more transistors to be integrated into a given area and is generally advantageous but also presents challenges as some features become very small.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a flowchart of operations in a method of fabricating a semiconductor device according to some embodiments.

FIGS. 2A-2H are cross-sectional views of a transistor structure at various stages in a manufacturing process according to some embodiments.

FIGS. 3A and 3B are cross-sectional views of the transistor structure of FIG. 2G according to some embodiments.

FIG. 4 is a cross-sectional view of a transistor structure according to some embodiments.

FIG. 5 is a cross-sectional view of a transistor structure according to some embodiments.

FIGS. 6A-6C are cross-sectional views of transistor structures according to some embodiments.

### DETAILED DESCRIPTION

This disclosure describes embodiments and examples of the subject matter set forth herein and, although specific examples of components, materials, values, steps, arrangements, or the like may be described, such examples are not limiting and other components, materials, values, steps, arrangements, or the like are contemplated.

As used herein, a term preceded by “a” or “an” (and “the” when antecedent basis is “a” or “an”) indicates both singular and plural of such term, unless indicated otherwise.

Further, like numbers are intended to denote like elements throughout this disclosure and the drawings, but like numbers or other referential descriptors do not imply a specific hierarchy or order. Likewise, references to “first,” “second,” “third,” or the like do not imply a specific order.

Further, a description of a first element being “on” a second element may include a case in which the first element is directly on the second element, i.e., the first and second elements are in direct contact, and may also include a case in which an additional element is between the first and second elements, e.g., a case in which the first and second elements are not in direct contact.

Further, the terms “comprises,” “comprising,” “includes,” “including,” “has,” “having,” and variations thereof indicate a non-exclusive inclusion. For example, a process, article, or apparatus that “comprises” a list or set of stated elements is not limited to only the stated elements, and may include other elements not expressly listed or stated.

Further, the term “or” is inclusive, not exclusive, such that the term “or” means “and/or” unless indicated otherwise. Thus, “A or B” means “A and/or B” and encompasses A alone, B alone, and both A and B, unless indicated otherwise.

Further, spatially relative terms, such as “beneath,” “below,” “lower,” “above,” “upper” and the like, may be used herein for ease of description to describe one element or feature's relationship to another element(s) or feature(s) as illustrated in the figures but do not imply a fixed orientation. The spatially relative terms are intended to encompass different orientations in addition to the orientation depicted in the figures.

Further, “source/drain(s)” may refer to a source or a drain, individually or collectively dependent upon the context.

In some embodiments, a transistor includes a gate structure adjacent to a channel region; source and drain regions adjacent to the channel region; a gate contact connected to the gate structure; and source/drain contacts connected to the source/drain regions. In some embodiments, the gate structure includes a conductive (i.e., electrically conductive) fill material (i.e., an electrically conductive material) at least partially surrounded by a work function (WF) layer, with the conductive fill material and the work function layer being separated from a channel region by a gate dielectric layer. In some embodiments, insulating (i.e., electrically insulating) gate spacers are disposed on sides of the gate dielectric layer and/or the gate structure. In some embodiments, the gate spacers are surrounded by a dielectric layer. In some embodiments, the dielectric layer includes an interlayer dielectric (ILD) layer. In some embodiments, the gate structure has an insulating layer thereon. In some embodiments the gate structure has an upper portion and a lower portion, and the upper portion of the gate structure is wider than the lower portion of the gate structure and overhangs the gate spacers. In some embodiments, the conductive fill material has an upper portion and a lower portion, and the upper portion of the conductive fill material is wider than the lower portion of the conductive fill material. The design of the transistor helps to enable fine tuning of the profile of the gate structure to reduce gate resistance (Rg) and helps to enable a device which has large pitch but provides high speed in comparison with other approaches.

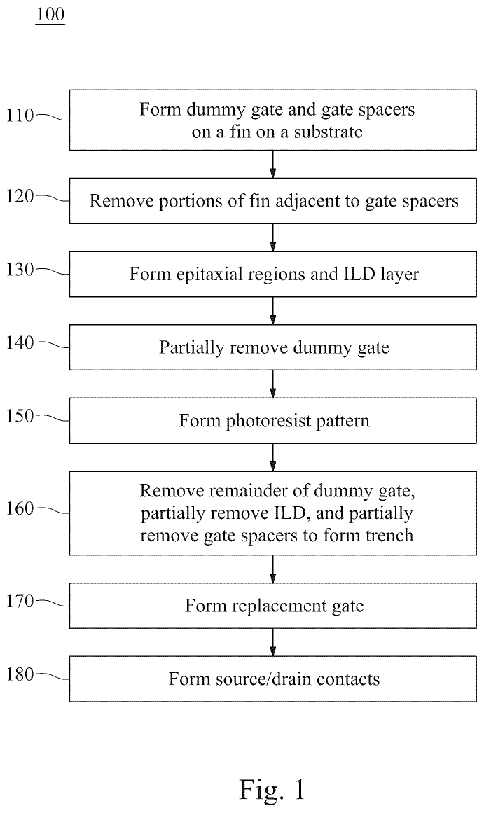

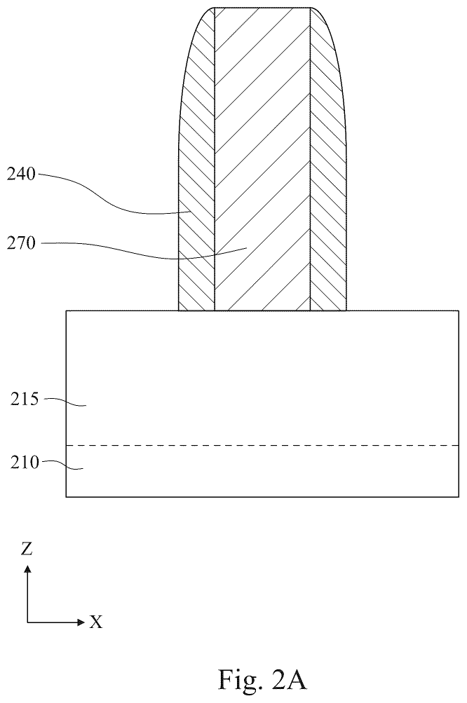

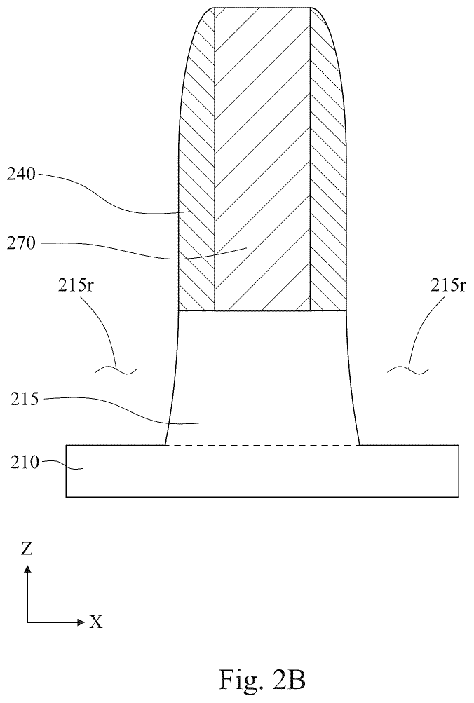

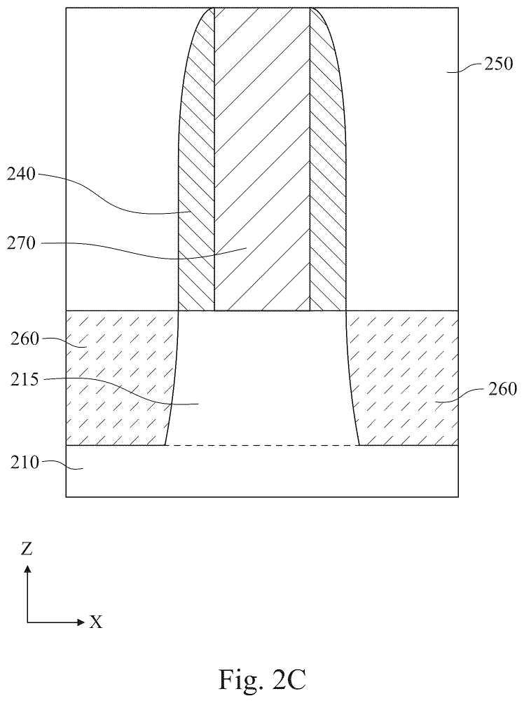

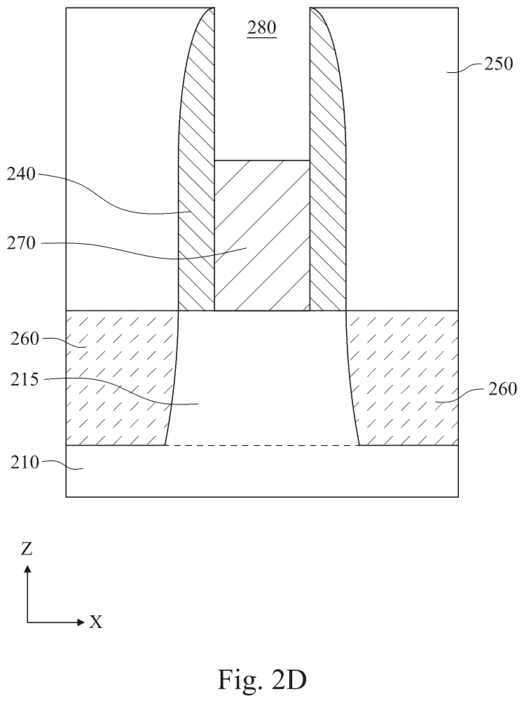

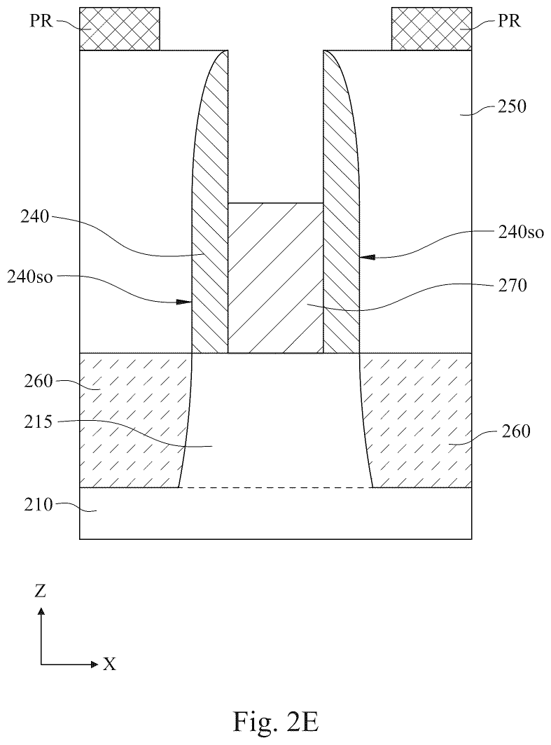

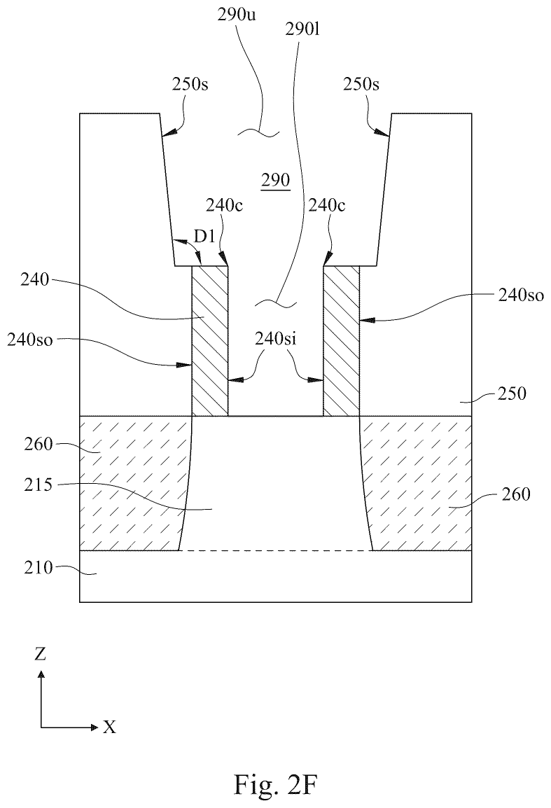

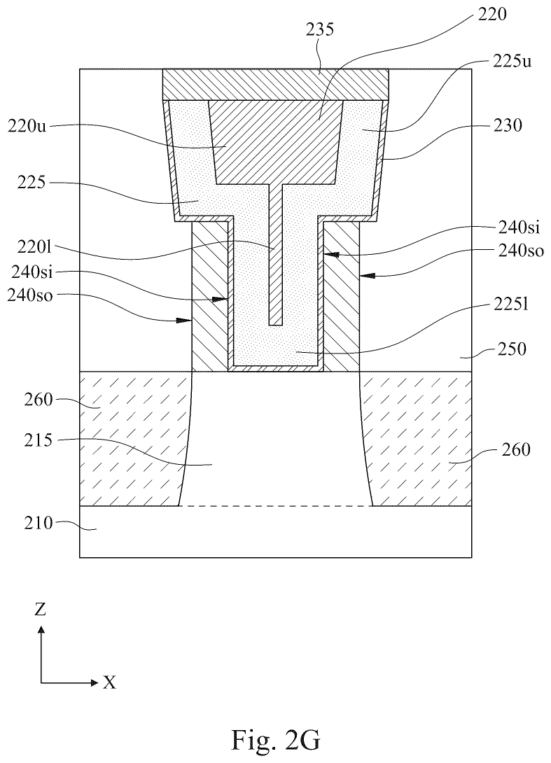

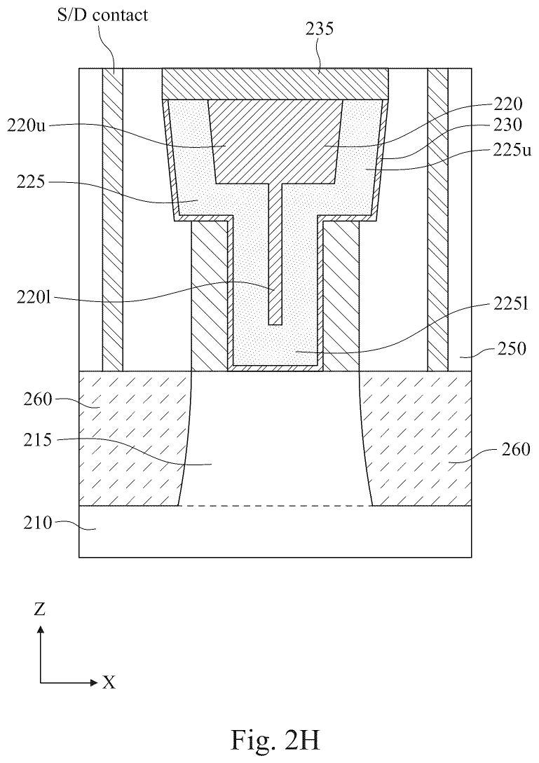

FIG. 1 is a flowchart of operations in a method of fabricating a semiconductor device according to some embodiments, and FIGS. 2A-2G are cross-sectional views of a transistor structure at various stages in a manufacturing process according to some embodiments.

Operations in FIG. 1 are part of a method 100 that forms a transistor using a gate-last process, e.g., a replacement metal gate (RMG) process, according to some embodiments.

In some embodiments, the transistor includes a field-effect transistor (FET). In some embodiments, the transistor includes a metal-oxide-semiconductor field-effect transistor (MOSFET). In some embodiments, the transistor includes a planar transistor, a finFET transistor, or the like.

Referring to FIGS. 1 and 2A, an operation 110 includes forming a dummy gate 270 on a fin 215 of a substrate 210, and forming gate spacers 240 on sidewalls of the dummy gate 270.

In some embodiments, the substrate 210 is a semiconductor substrate. In some embodiments, the substrate 210 is a bulk semiconductor substrate, a silicon-on-insulator (SOI) substrate, a semiconductor-on-insulator substrate, or the like. In some embodiments, the substrate 210 is doped with an n-type or p-type dopant, or is undoped. In some embodiments, the substrate 210 is or includes a semiconductor wafer such as a single-crystalline semiconductor wafer that is a section of a single crystal semiconductor ingot. In some embodiments, the substrate 210 includes a buried oxide layer.

In some embodiments, the fin 215 is a semiconductor material. In some embodiments, the fin 215 is of the same material as an uppermost region of the substrate 210. In some embodiments, the fin 215 includes silicon. In some embodiments, the transistor is a MOSFET and the dummy gate is formed on the substrate 210 rather than on the fin 215.

In some embodiments, the fin 215 is formed by reducing a thickness of the substrate 210 in regions adjacent to the fin 215. In some embodiments, the fin 215 is formed by etching or patterning the substrate 210. In some embodiments, the fin 215 is formed by patterning and etching the substrate 210 using a photolithography process that includes depositing a layer of photoresist material on the substrate, irradiating or exposing the photoresist material in accordance with a pattern corresponding to the fin 215, developing the photoresist material to remove a portion thereof, and using the remaining photoresist material to protect the underlying portions of the substrate 210 during etching. In some embodiments, the fin 215 is formed on the substrate 210 by a growth process such as an epitaxial growth process.

In some embodiments, the dummy gate 270 includes polysilicon (also referred to as polycrystalline silicon or poly-Si or PO) or polycrystalline silicon-germanium (poly-SiGe). In some embodiments, the dummy gate 270 includes polycrystalline silicon. In some embodiments, the dummy gate 270 is formed by depositing a layer, e.g., a polycrystalline silicon layer, and patterning the deposited layer to form the dummy gate 270. In some embodiments, the dummy gate is formed as one or more layers of one or more different materials.

In some embodiments, the gate spacers 240 are formed along sidewalls of the dummy gate 270 by depositing a dielectric layer on the substrate 210 to cover the dummy gate 270, and then partially removing the deposited dielectric layer such that the gate spacers 240 remain along the sidewalls of the dummy gate 270.

In some embodiments, the gate spacers 240 include a single layer structure. In some embodiments, the gate spacers 240 include a multilayer structure. In some embodiments, the gate spacers 240 include an insulating material. In some embodiments, the gate spacers 240 include silicon oxide, SiON, SiCN, SiOC, SiOCN, or SiN, or the like.

In some embodiments, forming the gate spacers 240 includes chemical vapor deposition (CVD), physical vapor deposition (PVD), atomic layer deposition (ALD), or the like.

In some embodiments, the partial removal of the deposited dielectric layer is performed using a process that includes an anisotropic etch operation. In some embodiments, the anisotropic etch operation forms the gate spacers 240 along the sidewalls of the dummy gate 270 by selectively removing horizontal portions of the dielectric layer relative to vertical portions of the dielectric layer, such that the etch operation results in vertically-oriented gate spacers 240 along the sidewalls of the dummy gate 270. In some embodiments, the anisotropic etch operation results in upper portions of the gate spacers 240 having a rounded profile that curves towards the dummy gate 270. In some embodiments, the forming of the gate spacers 240 along the sidewalls of the dummy gate 270 does not use a photoresist layer or pattern, or a lithography operation.

Referring to FIGS. 1 and 2B, in an operation 120 portions of the fin 215 adjacent to the gate spacers 240 are removed to form recesses 215r for source/drain regions.

In some embodiments, the gate spacers 240 are used to define a source/drain region (junction) profile. In some embodiments, the gate spacers 240 are used to offset doped regions from the gate structure for source/drain regions.

Referring to FIG. 2B, portions of the fin 215 exposed by the dummy gate 270 and the gate spacers 240 are removed or recessed to form the recesses 215r alongside the gate spacers 240.

In some embodiments, removing the portions of the fin 215 includes forming a photoresist layer or a capping layer (such as an oxide capping layer) over the structure of FIG. 2A, patterning the photoresist or capping layer to have openings that expose portions of the fin 215, and using an etching process to etch the exposed portions of the fin 215. In some embodiments, the fin 215 is etched using a dry etching process. In some embodiments, the etching process is a wet etching process, or combination dry and wet etching process. In some embodiments, removing the portions of the fin 215 includes a lithography process that includes coating a photoresist (e.g., spin-on coating), soft baking, mask aligning, exposure, post-exposure baking, developing the photoresist, rinsing, drying (e.g., hard baking), other suitable processes, or the like. In some embodiments, removing the portions of the fin 215 includes maskless photolithography, electron-beam writing, ion-beam writing, or the like. In some embodiments, removing the portions of the fin 215 includes a nanoimprint process. In some embodiments, a pre-cleaning process is performed to clean the recesses 215r using an HF solution or the like.

Referring to FIGS. 1 and 2C, in an operation 130, after the portions of the fin 215 are removed alongside the gate spacers 240, epitaxial layers 260 are formed in the recesses 215r to form source/drain regions of the fin 215, and an interlayer dielectric (ILD) layer 250 is formed on the substrate 210 at outer sides of the gate spacers 240.

In some embodiments, the epitaxial layers 260 are formed using one or more epitaxy or epitaxial (epi) processes, such that Si features, SiGe features, or the like are formed in a crystalline state at the source/drain regions. In some embodiments, a lattice constant of the epitaxial layers 260 is different than a lattice constant of the fin 215 so that a channel region of the fin 215 is strained or stressed by the epitaxial layers 260. In some embodiments, the strained or stressed channel region helps to improve carrier mobility and enhance the device performance. In some embodiments, the epitaxy process includes CVD deposition techniques (e.g., vapor-phase epitaxy (VPE) and/or ultra-high vacuum CVD (UHV-CVD)), molecular beam epitaxy, or the like. In some embodiments, the epitaxy process incorporates a dopant into the epitaxial layers 260. In some embodiments, the epitaxy process uses gaseous or liquid precursors that interact with the material (e.g., silicon) of the fin 215 at the source/drain regions. In some embodiments, a strained channel region is implemented to increase carrier mobility and enhance device performance. In some embodiments, the epitaxial layers 260 are doped using P-type dopants such as boron or BF₂, N-type dopants such as phosphorus or arsenic, or the like. In some embodiments, a junction implant process is performed to dope the epitaxial layers 260. In some embodiments, an annealing process, e.g., rapid thermal annealing (RTA) and/or laser annealing, is performed to activate the epitaxial layers 260.

In some embodiments, the ILD layer 250 includes an insulating material such as silicon oxide, silicon nitride, silicon oxynitride, silicon carbide, SiBN, SiCBN, tetraethoxysilane (TEOS), phosphosilicate glass (PSG), borophosphosilicate glass (BPSG), a low-k dielectric material, a combination thereof, or the like. Examples of low-k dielectric materials include fluorinated silica glass (FSG), carbon doped silicon oxide, amorphous fluorinated carbon, parylene, bis-benzocyclobutenes (BCB), polyimide, and the like. In some embodiments, the ILD layer 250 includes a single layer. In some embodiments, the ILD layer 250 includes multiple layers.

In some embodiments, the ILD layer 250 is formed by CVD, ALD, spin-on-glass (SOG), or the like. In some embodiments, a chemical-mechanical planarization (CMP) process is used to planarize the ILD layer 250 and expose the top of the dummy gate 270.

In FIG. 2C, the dummy gate 270 and the gate spacers 240 are on the fin 215 and have a common bottom that is at about a same level as a top of the epitaxial layers 260. The gate spacers 240 are along sidewalls of the dummy gate 270 and completely cover the sidewalls of the dummy gate 270.

Referring to FIGS. 1 and 2D, in an operation 140 a portion of the dummy gate 270 is removed, forming an opening 280 with the gate spacers 240 at sides thereof.

In some embodiments, the dummy gate 270 is partially removed using an etch process, e.g., a wet etch process or a dry etch process, that selectively removes the material of the dummy gate 270 relative to the material of the gate spacers 240. In some embodiments, the wet etch process employs an etchant that includes ammonium hydroxide or the like. In some embodiments, the dummy gate 270 is partially removed using a dry etch process, or a combination of dry and wet etch processes. In some embodiments, the dummy gate 270 is partially removed using an anisotropic etch operation. In some embodiments, the material of the dummy gate 270 is partially removed using an etching process that includes a dry etch process using reaction gas(es) that selectively etch the dummy gate material relative to the materials of the gate spacers 240 and the ILD layer 250. In some embodiments, the dummy gate 270 is partially removed without using a mask.

Referring to FIGS. 1 and 2E, in an operation 150 a photoresist pattern ‘PR’ is formed on the ILD layer 250 to serve as an etch mask. In FIG. 2E, the photoresist pattern PR has an opening that exposes upper surfaces of the partially removed dummy gate 270, the gate spacers 240, and a region of the ILD layer 250 beyond outer sidewalls 240so of the gate spacers 240.

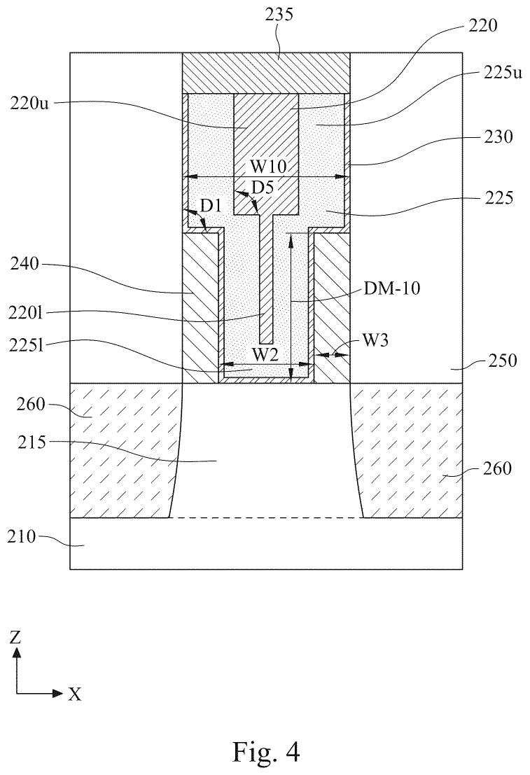

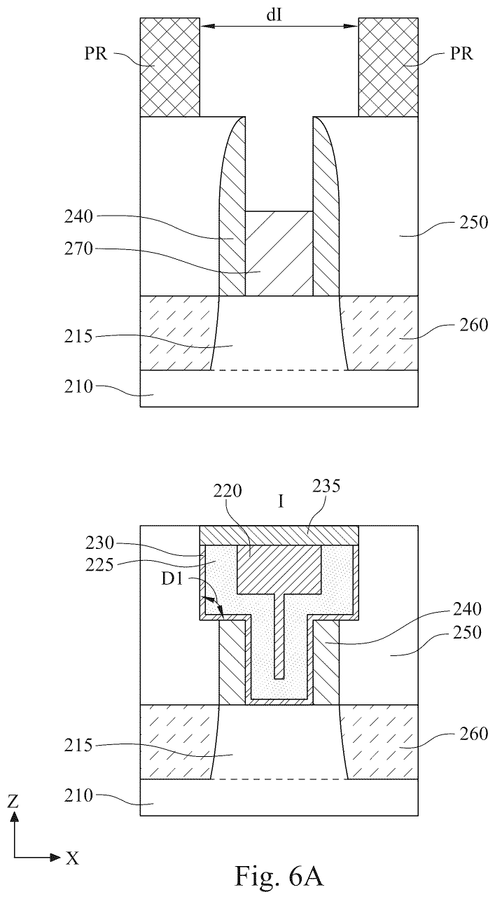

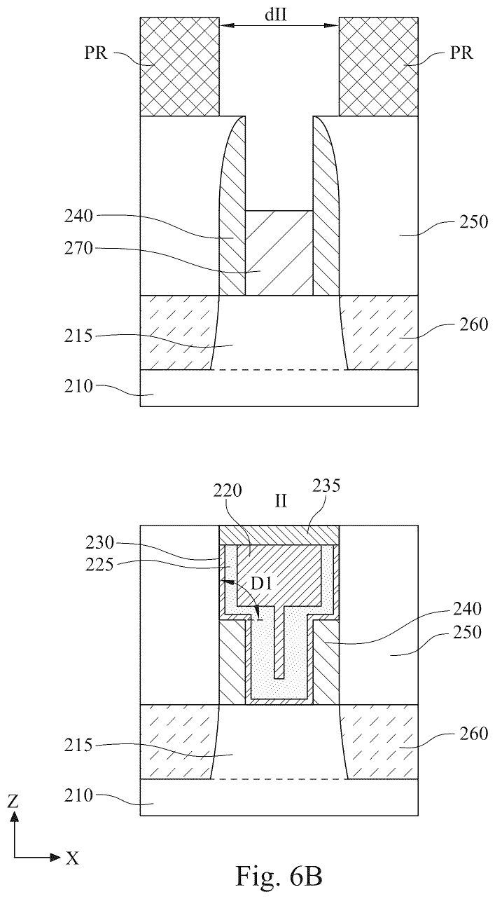

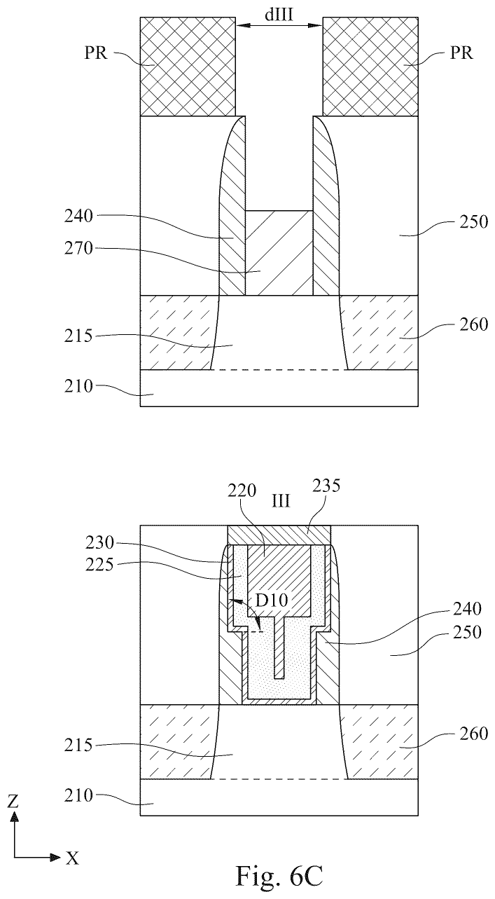

In some embodiments, the photoresist pattern PR exposes the upper surfaces of the partially removed dummy gate 270 and the gate spacers 240 while lateral boundaries of the opening in the photoresist pattern PR are substantially aligned with the outer sidewalls 240so of the gate spacers 240 (see also FIG. 4 and transistor structure II in FIG. 6B).

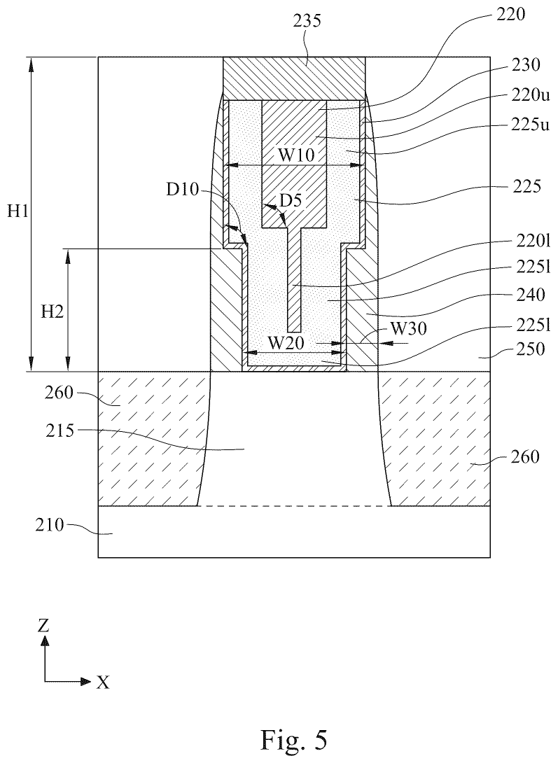

In some embodiments, the photoresist pattern PR exposes the upper surface of the dummy gate 270 while lateral boundaries of opening in the photoresist pattern PR are closer together than the outer sidewalls 240so of the gate spacers 240 (see also FIG. 5 and transistor structure III in FIG. 6C).

Referring to FIGS. 1 and 2F, in an operation 160 the photoresist pattern PR is used as an etch mask in one or more etch processes that remove the remaining part of the dummy gate 270, portions of the gate spacers 240, and portions of the ILD layer 250, resulting in a stepped opening or T-shaped trench 290, and the photoresist pattern PR is removed.

In FIG. 2F, the T-shaped trench 290 has a wider upper portion 290u and a narrower lower portion 2901.

In some embodiments, a step where the upper portion 290u of the T-shaped trench 290 transitions to the lower portion 2901 is sharp at corners 240c of the gate spacers 240. In some embodiments, the step is rounded at the corners 240c due to etching.

In FIG. 2F, the removal of portions of the gate spacers 240 and portions of the ILD layer 250 results in the upper portion 290u of the T-shaped trench 290 being bounded by sidewalls 250s of the ILD layer 250, with the sidewalls 250s of the ILD layer 250 being spaced apart by a greater distance than the outer sidewalls 240so of the gate spacers 240, i.e., the ILD layer 250 is removed laterally beyond the outer sidewalls 240so of the gate spacers 240 (see also transistor structure I in FIG. 6A). Thus, the sidewalls 250s of the ILD layer 250 that form the sides of the upper portion 290u of the T-shaped trench 290 are spaced apart by a distance that is greater than a distance between the outer sidewalls 240so of the gate spacers 240.

In some embodiments, the sidewalls 250s of the ILD layer 250 are spaced apart by a same distance as the outer sidewalls 240so of the gate spacers 240, i.e., the ILD layer 250 is removed to be aligned with the outer sidewalls 240so of the gate spacers 240 (see FIG. 4 and transistor structure II in FIG. 6B). That is, the sidewalls 250s of the ILD layer 250 that form the side of the upper portion 290u of the T-shaped trench 290 are substantially aligned with the outer sidewalls 240so of the gate spacers 240.

In some embodiments, the sidewalls 250s of the ILD layer 250 are spaced apart by a distance that is less than the distance between the outer sidewalls 240so of the gate spacers 240 and greater than a distance between inner sidewalls 240si of the gate spacers 240, while the gate spacers 240 remain for a substantial height of or a full height of the T-shaped trench 290 (see FIG. 5 and transistor structure III in FIG. 6C, in which the height of the gate spacers 240 is such that the gate spacers 240 extend vertically to vertically overlap an insulating layer such as a self-aligned contact (SAC) layer 235 (i.e., an imaginary horizontal line that passes through one of the gate spacers 240 also passes through the SAC layer 235)). In this case, the step in the T-shaped trench 290 is formed in the gate spacers 240, corresponding to a step from dimension W10 to dimension W20 of FIG. 5.

In FIG. 2F, the sidewalls 250s of the ILD layer 250 are formed to be sloped at an angle D1 of greater than 90 degrees (with 90 degrees being vertical or parallel to the Z axis) using control of a sidewall removal process.

In some embodiments, the sidewalls 250s of the ILD layer 250 are vertical, i.e., such that D1 is substantially 90 degrees (see, e.g., FIG. 4).

In some embodiments, the photoresist pattern PR is removed along with the remaining part of the dummy gate 270, portions of the gate spacers 240, and portions of the ILD layer 250. In some embodiments, the photoresist pattern PR is removed in a separate operation after removing the remaining part of the dummy gate 270, portions of the gate spacers 240, and portions of the ILD layer 250.

In some embodiments, removing the remaining part of the dummy gate 270, portions of the gate spacers 240, and portions of the ILD layer 250 involves a first operation that removes the remaining part of the dummy gate 270 and a second operation that removes portions of the gate spacers 240 and portions of the ILD layer 250. In some embodiments, the first operation precedes the second operation. In some embodiments, the first operation follows the second operation. In some embodiments, removing the remaining part of the dummy gate 270, portions of the gate spacers 240, and portions of the ILD layer 250 is performed using a wet etch or an isotropic etch. In some embodiments, the first and second operations are performed using different wet etch or isotropic etch chemistries.

Referring to FIGS. 1 and 2G, in an operation 170 a replacement gate is formed.

Operation 170 includes sequentially forming a gate dielectric layer 230, a work function layer 225, a filling conductor 220, and the SAC layer 235. In some embodiments, forming the gate dielectric layer 230, the work function layer 225, and the filling conductor 220 are operations that are included in a metal gate loop.

In FIG. 2G, the gate dielectric layer 230 is formed on the fin 215.

In some embodiments, the gate dielectric layer 230 is formed to line the entirety of the T-shaped trench 290 of FIG. 2F that was formed by removing the remaining part of the dummy gate 270, portions of the gate spacers 240, and portions of the ILD layer 250. In some embodiments, the gate dielectric layer 230 is formed to wrap an entire exposed area of the fin 215. In some embodiments, the gate dielectric layer 230 is formed, e.g., patterned, to wrap a central portion of the fin 215 and expose a portion of the fin 215.

In some embodiments, the gate dielectric layer 230 includes one or more layers of insulating material(s) such as silicon oxide or a high-k material. In some embodiments, the gate dielectric layer 230 includes a multilayer structure such as a layer of silicon oxide (e.g., as an interfacial layer) and another layer of a high-k material. In some embodiments, the gate dielectric layer 230 is a conformal layer. In some embodiments, a thickness of the gate dielectric layer 230 on the top of the fin 215 is different from a thickness of the gate dielectric layer 230 on a sidewall of the fin 215.

In some embodiments, forming the gate dielectric layer 230 includes a process such as thermal oxidation, chemical vapor deposition, sputtering, or the like.

In some embodiments, the gate dielectric layer 230 includes one or more of a high-k dielectric material such as metal oxides, metal nitrides, metal silicates, transition metal-oxides, transition metal-nitrides, transition metal-silicates, oxynitrides of metals, metal aluminates, zirconium silicate, zirconium aluminate, or the like. In some embodiments, the gate dielectric layer 230 includes one or more of hafnium oxide (HfO₂), hafnium silicon oxide (HfSiO), hafnium silicon oxynitride (HfSiON), hafnium tantalum oxide (HfTaO), hafnium titanium oxide (HfTiO), hafnium zirconium oxide (HfZrO), lanthanum oxide (LaO), zirconium oxide (ZrO), titanium oxide (TiO), tantalum oxide (Ta₂O₅), yttrium oxide (Y₂O₃), strontium titanium oxide (SrTiO₃, STO), barium titanium oxide (BaTiO₃, BTO), barium zirconium oxide (BaZrO), hafnium lanthanum oxide (HfLaO), lanthanum silicon oxide (LaSiO), aluminum silicon oxide (AlSiO), aluminum oxide (Al₂O₃), silicon nitride (Si₃N₄), oxynitride (SiON), or the like. In some embodiments, the gate dielectric layer 230 is formed of a different material than the ILD layer 250.

In some embodiments, forming the gate dielectric layer 230 is performed using chemical vapor deposition (CVD), physical vapor deposition (PVD), atomic layer deposition (ALD), thermal oxide, ozone oxidation, combinations thereof, or the like.

In FIG. 2G, the work function layer 225 is formed on the gate dielectric layer 230.

In FIG. 2G, the lateral extent of the work function layer 225 extends beyond the outer sidewalls 240so of the gate spacers 240.

In some embodiments, the lateral extent of the work function layer 225 is narrower than the outer sidewalls 240so of the gate spacers 240 but wider than the inner sidewalls 240si of the gate spacers 240 (see, e.g., FIG. 5 and transistor structure III in FIG. 6C).

In some embodiments, the work function layer 225 adjusts a threshold voltage of the transistor. In some embodiments, the transistor is a P-type FET (PFET) and includes a P-type work function metal or metal-containing material such as TiN, TaC, TaN, Co, Ru, Mo, Al, or WN, or a silicide such as ZrSi₂, MoSi₂, TaSi₂, or NiSi₂, or other P-type work function layers, or combinations thereof. In some embodiments, the work function layer 225 includes a P-type work function material to provide a desired work function value for a P-type gate of a P-type semiconductor device. In some embodiments, the transistor is an N-type FET (NFET) and includes an N-type work function metal or metal-containing material such as Ti, Ag, Al, TiAl, TaAl, TaAlC, TaAlN, TaC, TaCN, TaSiN, Mn, or Zr, or other N-type work function layers, or combinations thereof. In some embodiments, the work function layer 225 includes an N-type work function material to provide a desired work function value for an N-type gate of an N-type semiconductor device.

In some embodiments, the work function layer 225 is a conformal layer that has a generally uniform thickness (width) throughout. In some embodiments, different portions of the work function layer 225 have different widths.

In some embodiments, the work function layer 225 is deposited using one or more of atomic layer deposition (ALD), evaporation, sputtering, chemical vapor deposition (CVD), PVD, remote plasma CVD (RPCVD), plasma enhanced CVD (PECVD), metal organic CVD (MOCVD), plating, combinations thereof, or the like. In some embodiments, the work function layer 225 is formed by conformal deposition of a work function material. In some embodiments, the work function material is deposited across an entire region of the substrate 210 and then removed from regions surrounding the gate structure using a CMP process, and then the work function material is partially removed from upper inner sidewalls of the gate spacers 240 by protecting a lower portion of the work function material, e.g., using a masking material, performing an etching process such as an etch back process, and then removing the masking material.

In FIG. 2G, the filling conductor 220 is formed on the work function layer 225.

In FIG. 2G, the filling conductor 220 has a stepped or ‘T’ shape with a wider upper portion 220u (cap) connected to a narrower lower portion 2201 (tail).

In some embodiments, the gate dielectric layer 230 and the work function layer 225 are conformal layers that conform to the sidewalls of the T-shaped trench 290 and have a substantially uniform thickness, and the filling conductor 220 is formed in the remaining volume of the T-shaped trench 290 such that the shape and slope of the sidewalls of the T-shaped trench 290 are reflected in the resultant shape and slope of the sidewalls of the filling conductor 220.

In FIG. 2G, the filling conductor 220 overhangs the gate spacers 240, i.e., a width, as determined parallel to the X axis, of the upper portion 220u of the filling conductor 220 is greater than a distance, as determined parallel to the X axis, between the inner sidewalls 240si of the gate spacers 240.

In some embodiments, the filling conductor 220 is wider than in FIG. 2G and overhangs the ILD layer 250 above the gate spacers 240, i.e., the lateral extent of the filling conductor 220 extends beyond the outer sidewalls 240so of the gate spacers 240.

In some embodiments, the filling conductor 220 is formed to a full height of the ILD layer 250. In some embodiments, the filling conductor 220, the work function layer 225, and the gate dielectric layer 230 are partially removed using an etching process such as an etch back process, and the SAC layer 235 is formed in a space created by thereby.

In FIG. 2G, the lower portion 2201 of the filling conductor 220 is present in a lower portion 2251 of the work function layer 225. The upper portion 220u of the filling conductor 220 extends laterally across the work function layer 225, which helps to increase a contact area between the filling conductor 220 and the work function layer 225 and helps to improve, i.e., reduce, gate resistance Rg.

In FIG. 2G, the filling conductor 220 and the work function layer 225 are laterally bounded by the gate dielectric layer 230. In some embodiments, maintaining a lateral extent of the filling conductor 220 and the work function layer 225 within the boundaries of the gate dielectric layer 230 helps to reduce gate leakage and avoids shorts.

In some embodiments, filling conductor 220 is formed by filling in a region between inner sidewalls of the work function layer 225 such that the width of the filling conductor is a function of the width of the T-shaped trench 290, the thickness of the gate dielectric layer 230, and the thickness of the work function layer 225.

In some embodiments, the filling conductor 220 includes one or more layers of conductive metal or metal-containing material(s). In some embodiments, the filling conductor 220 is or includes tungsten, aluminum, copper, or the like. In some embodiments, the filling conductor 220 is predominantly tungsten. In some embodiments, the material of the filling conductor 220 is more conductive than the material of the work function layer 225.

In some embodiments, forming the filling conductor 220 includes a deposition process such as CVD, PVD, ALD, or the like, after which a CMP process is used to remove excess filling conductor 220 that overfills the T-shaped trench 290.

In some embodiments, the top of the filling conductor 220 is processed to be recessed. In some embodiments, the top of the filling conductor 220 is recessed using an etchant that has high selectivity between the filling conductor 220 and the gate spacers 240. In some embodiments, the top of the filling conductor 220 and the top of the work function layer 225 are processed to be recessed. In some embodiments, the top of the filling conductor 220, the top of the work function layer 225, and the top of the gate dielectric layer 230 are processed to be recessed. In some embodiments, a metal gate etch back (MGEB) process is used to recess the top of the gate structure and the gate dielectric layer 230. In some embodiments, the metal gate etch back process includes a plasma etching process employing one or more etchants such as a fluorine-containing gas (e.g., one or more of CF₄, SF₆, CH₂F₂, CHF₃, or C₂F₆) and/or a chlorine-containing gas (e.g., one or more of Cl₂, CHCl₃, CCl₄, BCl₃, or SCl₄).

In FIG. 2G, the SAC layer 235 is formed on the recessed filling conductor 220, work function layer 225, and gate dielectric layer 230.

In FIG. 2G, the SAC layer 235 is formed to be the full width of the filling conductor 220, the work function layer 225, and the gate dielectric layer 230, i.e., the SAC layer 235 covers all of the filling conductor 220, the work function layer 225, and the gate dielectric layer 230.

In FIG. 2G, the SAC layer 235 horizontally overlaps the gate spacers 240. In other words, an imaginary vertical line that passes through one of the gate spacers 240 also passes through the SAC layer 235.

In some embodiments, SAC layer 235 includes silicon oxide, silicon nitride, silicon oxynitride, silicon carbide, a low-dielectric constant dielectric material, or the like. In some embodiments, SAC layer 235 includes silicon nitride.

In some embodiments, SAC layer 235 is formed using a deposition process, such as ALD, CVD, PVD, or the like. In some embodiments, after the deposition process, a CMP process is performed to remove portions of the SAC layer 235 that extend over the ILD layer 250.

Referring to FIGS. 1 and 2H, in an operation 180 a resultant structure of operation 170 and FIG. 2G is processed to form source/drain (S/D) contacts that contact the epitaxial layers 260 adjacent to the gate.

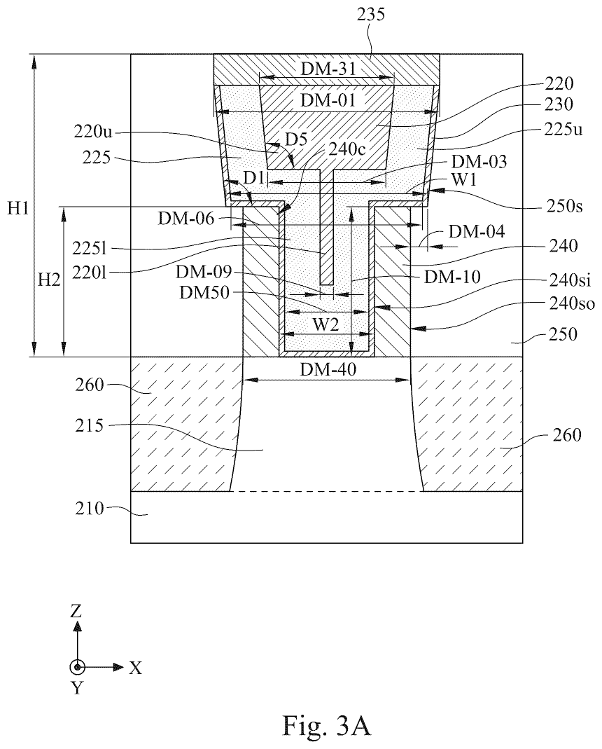

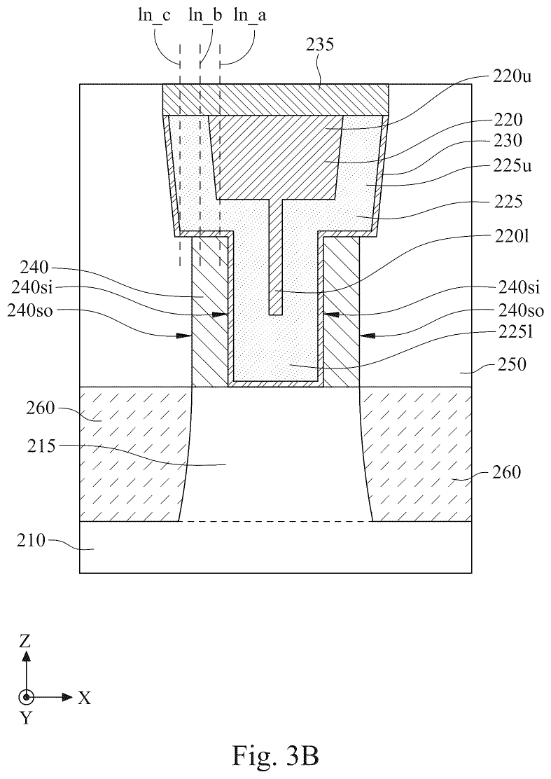

FIG. 3A is an illustration of the transistor structure of FIG. 2G with annotations showing various dimensions and angles.

In FIG. 3A, a width of an upper portion of the gate structure (dimension W1) is greater than a width of a lower portion of the gate structure (dimension W2) (i.e., W1>W2). In some embodiments, this structure allows for a greater width of the filling conductor 220 and helps to reduce gate resistance Rg while maintaining device performance. W1>W2 provides for a relatively greater amount of the filling conductor 220 than a case where the entire gate structure has the width W2. In some embodiments, gate resistance Rg decreases with increased width W1. In some embodiments, increases in W1 are constrained by the need to avoid the gate structure becoming too close to an adjacent structure such as a contact. In some embodiments, the relationship of W1 to W2 decides a process window.

In FIG. 3A, upper portion of the gate structure overhangs the gate spacers 240 by at least a dimension DM-04. In some embodiments, DM-04 is sufficiently small to avoid the gate structure becoming too close to an adjacent structure, e.g., to avoid bridging to a source/drain contact.

In FIG. 3A, the fin 215 has sidewalls that are aligned with outer sidewalls of the gate spacers 240.

In some embodiments, the gate spacers 240 have a lateral extent (dimension DM-40) that is less than a lateral extent of the sidewalls of the fin 215 such that the fin 215 is wider than dimension DM-40. In some embodiments, the gate spacers 240 have a lateral extent that is greater than that of the sidewalls of the fin 215 such that the fin 215 is narrower than the dimension DM-40 and the gate spacers 240 laterally overhang beyond the sidewalls of the fin 215.

In FIG. 3A, an upper portion 225u of the work function layer 225 has a lateral dimension (dimension DM-06) that is greater than the lateral extent of the gate spacers 240 (dimension DM-40).

In FIG. 3A, the upper portion 220u of the filling conductor 220 has a lateral dimension (dimension DM-03) that is greater than a lateral extent of the lower portion 2201 of the filling conductor 220 (dimension DM-09). In other words, the upper portion 220u of the filling conductor 220 is wider than the lower portion 2201 of the filling conductor. Here, “wider” refers to a dimension determined parallel to the X axis. Relative to a structure in which the filling conductor 220 is a single width throughout (e.g., having the width DM-09 throughout an entire height of the filling conductor 220), the wider upper portion 220u of the filling conductor 220 makes forming the lower portion 2201 easier by effectively reducing the aspect ratio of the filling conductor 220 as a whole, and helps lower gate resistance (Rg).

In some embodiments, the width of the lower portion 2201 of the filling conductor 220 (dimension DM-09) is substantially constant with increasing distance from the substrate.

In some embodiments, the upper portion 220u of the filling conductor 220 is wider than the lower portion 2201 of the filling conductor for a substantial or entire length of the gate structure, i.e., a length in a Y axis direction in FIG. 3A (in/out of the page).

In some embodiments, a ratio of the width of the upper portion 220u of the filling conductor 220 to the width of the lower portion 2201 of the filling conductor 220 (DM-03:DM-09) is substantially equal to a ratio of the width of the upper portion of the gate structure to the width of the lower portion of the gate structure (W1:W2).

In FIG. 3A, a sidewall angle of the upper portion 220u of the filling conductor 220 is angle D5.

In some embodiments angles D1 and D5 are equal to one another, the width of the upper portion 220u of the filling conductor is a constant fraction of the width W1 of the upper portion of the gate structure, and the filling conductor 220 has a cross sectional shape in the X-Z plane that corresponds to, while being smaller than, a cross-sectional shape of the gate structure in the X-Z plane. Enlarging the width of the upper portion of the gate structure and the upper portion 220u of the filling conductor (i.e., enlarging W1 and DM-03) increases the amount and surface area of the filling conductor 220 and helps to reduce the gate resistance Rg.

In FIG. 3A, the upper portion 220u of the filling conductor 220 has a lateral dimension (dimension DM-03) that is greater than a distance between the inner sidewalls 240si of the gate spacers 240 (see dimension W2). In other words, the upper portion 220u of the filling conductor 220 is wider than the width W2 of the lower portion of the gate structure (i.e., wider than the distance between the inner sidewalls 240si of the gate spacers 240), and the upper portion 220u of the filling conductor 220 overhangs the inner sidewalls 240si of the gate spacers 240.

In some embodiments, the upper portion 220u of the filling conductor 220 has a lateral dimension (e.g., dimension DM-03 at the bottom or dimension DM-31 at the top of the upper portion 220u) that is greater than a distance between the outer sidewalls 240so of the gate spacers 240 (dimension DM-40).

In some embodiments, the upper portion 220u of the filling conductor 220 has a lateral dimension (DM-03) that is greater than a lateral extent of the lower portion 2201 (dimension DM-09) but less than the distance between the inner sidewalls 240si of the gate spacers 240 (see, e.g., FIGS. 4 and 5).

In FIG. 3A, the width of the upper portion 220u of the filling conductor 220 transitions in a step manner to the width of the lower portion 2201 of the filling conductor 220, i.e., there is a step from dimension DM-03 to dimension DM-09.

In some embodiments, the step in the filling conductor 220 is rounded. In some embodiments, the width of the upper portion 220u of the filling conductor 220 transitions gradually or continuously to the width of the lower portion 2201 of the filling conductor 220.

In FIG. 3A, the overall or outer width of the upper portion 225u of the work function layer 225 transitions in a step manner to the overall or outer width of the lower portion 2251 of the work function layer 225, i.e., there is a step from dimension DM-06 to dimension DM-50.

In some embodiments, the step in the work function layer 225 is rounded. In some embodiments, the overall or outer width of the upper portion 225u of the work function layer 225 transitions in a curved step manner to the overall or outer width of the lower portion 2251 of the work function layer 225, i.e., there is a curved step from dimension DM-06 to dimension DM-50, e.g., the upper inner corners 240c of the gate spacers 240 are rounded, e.g., due to being rounded during an etching operation. In some embodiments, the overall or outer width of the upper portion 225u of the work function layer 225 transitions gradually or continuously to the overall or outer width of the lower portion 2251 of the work function layer 225.

In FIG. 3A, a height of the lower portion of the gate structure (dimension H2) and an overall height of the gate structure with the SAC layer 235 (see dimension H1) satisfy the relationship H2/H1≥⅓. In some embodiments, maintaining H2≥H1*⅓ helps provide high device performance.

In FIG. 3A, the angle D1 of the sidewalls 250s of the ILD layer 250 satisfies the relationship 120 degrees≥D1≥90 degrees. The relationship D1>90 degrees allows the upper surface width of the upper portion 220u of the filling conductor 220 (dimension DM-31) to be greater than the lower surface width of the upper portion 220u of the filling conductor 220 (dimension DM-03) and simplifies formation of the filling conductor 220. The relationship D1≤ 120 degrees helps to maintain a distance between the gate structure and an adjacent structure such as a source/drain contact (see, e.g., FIG. 2H showing the source/drain contacts).

In FIG. 3A, the sidewall angle of the upper portion 220u of the filling conductor 220 (the angle D5) satisfies the relationship 120 degrees≥D5≥90 degrees. In some embodiments, 120 degrees≥D5≥90 degrees simplifies formation, e.g., filling, of the filling conductor 220. In FIG. 3A, D1=D5.

In FIG. 3A, D1>90 degrees, which results in DM-01>DM-06, i.e., the upper portion 225u of the work function layer 225 gets wider (as determined parallel to the X axis) with increasing distance from the substrate. Also, D5>90 degrees results in DM-31>DM-03, the upper portion 220u of the filling conductor 220 gets wider (as determined parallel to the X axis) with increasing distance from the substrate.

In FIG. 3A, the gate spacers 240 have a height (DM-10) that corresponds to the height of the lower portion of the gate structure (H2).

FIG. 3B is an illustration of the transistor structure of FIG. 2G with annotations showing overlapping features.

In FIG. 3B, the upper portion 220u of the filling conductor 220 is wider than a distance between the inner sidewalls 240si of the gate spacers 240 such that the upper portion 220u of the filling conductor 220 overhangs the gate spacers 240. In other words, a first imaginary vertical line ln_a passes through the upper portion 220u of the filling conductor 220 and one of the gate spacers 240 (it will be appreciated that the same is true for the opposite side of the gate structure in the case that the gate structure has mirror image symmetry). Herein, references to “vertical” refer to elements that are parallel to the Z axis.

In FIG. 3B, the work function layer 225 also overhangs the gate spacers 240. In other words, a second imaginary vertical line ln_b passes through the upper portion 225u of the work function layer 225 and one of the gate spacers 240 (it will be appreciated that the same is true for the opposite side of the gate structure in the case that the gate structure has mirror image symmetry).

In FIG. 3B, the work function layer 225 overhangs the ILD layer 250. In other words, a third imaginary vertical line ln_c passes through the upper portion 225u of the work function layer 225 and the ILD layer 250 (it will be appreciated that the same is true for the opposite side of the gate structure in the case that the gate structure has mirror image symmetry).

FIG. 4 is an illustration of a transistor structure according to some embodiments.

FIG. 4 is an illustration of a transistor structure according to some embodiments that generally corresponds to the transistor structure of FIGS. 2G, 3A, and 3B but has vertical sides aligned with the outer sidewalls 240so of the gate spacers 240. Elements not expressly described in connection with FIG. 4 are assumed to be substantially the same as those described above in connection with FIGS. 2G, 3A, and 3B.

In FIG. 4, an overall width W10 of the upper portion of the gate structure is substantially equal to an overall width of the lower portion of the gate structure including the gate spacers 240. Thus, in FIG. 4, W10=W2+2*W3.

In FIG. 4, the sidewalls 250s of the ILD layer 250 and the sides of the upper portion 220u of the filling conductor 220 are vertical, i.e., having angles D1 and D5 that are substantially equal to 90 degrees. In FIG. 3A, D1=D5.

In some embodiments, D1 and D5 are equal to one another, and satisfy the relationships 120 degrees≥D1≥90 degrees and 120 degrees≥D5≥90 degrees.

In FIG. 4, the upper portion 220u of the filling conductor 220 has a width that is less than the distance between the inner sidewalls 240si of the gate spacers 240. In other words, an imaginary vertical line that passes through the upper portion 220u of the filling conductor 220 would not pass through one of the gate spacers 240.

In some embodiments, the upper portion 225u of the work function layer 225 is made relatively thinner and the upper portion 220u of the filling conductor 220 is made correspondingly larger, e.g., so that an imaginary vertical line does pass through the upper portion 220u of the filling conductor 220 and one of the gate spacers 240 (see imaginary line ln_a in FIG. 3B).

In FIG. 4, the upper portion 220u of the filling conductor 220 is wider than the lower portion 2201 of the filling conductor, which makes forming the lower portion 2201 easier and helps to reduce gate resistance Rg while maintaining device performance.

In FIG. 4, the gate spacers 240 have a height (dimension DM-10) that corresponds to the height of the lower portion of the gate structure, i.e., the gate spacers 240 are not a full height of the gate structure. In some embodiments, the height of the gate spacers 240 being less than a full height of the gate structure simplifies fabrication of the gate by allowing for greater variation in etch characteristics, due to the gate spacers 240 having a greater thickness overall.

FIG. 5 is an illustration of a transistor structure according to some embodiments.

FIG. 5 is an illustration of a transistor structure in which outer sidewalls of the upper portion of the gate structure are closer together than the outer sidewalls 240so of the gate spacers 240 but farther apart than the inner sidewalls 240si of the gate spacers 240. Elements not expressly described in connection with FIG. 5 are assumed to be substantially the same as those described above in connection with FIGS. 3B and 4.

In FIG. 5, the sides of the upper portion 220u of the filling conductor 220 are vertical, i.e., the angle D5 is substantially equal to 90 degrees. Also, the gate spacers 240 have a step therein that is substantially square such that an enclosed angle D10 of the step is substantially equal to 90 degrees. In FIG. 5, D10=D5.

In some embodiments, D10 and D5 are equal to one another and satisfy the relationships 120 degrees≥D10≥90 degrees and 120 degrees≥D5≥90 degrees.

In FIG. 5, the upper portion 220u of the filling conductor 220 has a width that is less than the distance between the inner sidewalls 240si of the gate spacers 240. In other words, an imaginary vertical line that passes through the upper portion 220u of the filling conductor 220 would not pass through one of the gate spacers 240.

In some embodiments, the upper portion 225u of the work function layer 225 is made relatively thinner and the upper portion 220u of the filling conductor 220 is made correspondingly larger, e.g., so that an imaginary vertical line does pass through the upper portion 220u of the filling conductor 220 and one of the gate spacers 240 (see imaginary line ln_a in FIG. 3B).

In FIG. 5, the upper portion 220u of the filling conductor 220 is wider than the lower portion 2201 of the filling conductor, which makes forming the lower portion 2201 easier and helps to reduce gate resistance Rg while maintaining device performance.

In FIG. 5, the gate spacers 240 have a height that is sufficient to cover substantially the full height of the gate structure. Thus, the entirety of the gate dielectric layer 230 is separated from the surrounding ILD layer 250 by the gate spacers 240. In some embodiments, the entirety of the gate dielectric layer 230 being separated from the surrounding ILD layer 250 by the gate spacers 240 helps to improve isolation of the gate.

FIGS. 6A-6C are cross-sectional views of transistor structures according to some embodiments.

FIGS. 6A-6C include three photoresist patterns PR and three corresponding transistor structures.

The photoresist pattern PR of FIG. 6A corresponds to the previously-described photoresist pattern PR in FIG. 2E.

The photoresist pattern PR in FIG. 6A has an opening with lateral boundaries that are spaced apart by a distance dI (as determined parallel to the X axis). The photoresist pattern PR in FIG. 6B has an opening with lateral boundaries that are spaced apart by a distance dII, which is less than the distance dI. The lateral boundaries of the opening in the photoresist pattern PR in FIG. 6B are substantially aligned with the outer sidewalls of the gate spacers 240. The photoresist pattern PR in FIG. 6C has an opening with lateral boundaries that are spaced apart by a distance dIII, which is less than the distance dII.

The photoresist pattern PR in FIG. 6A is used to form the transistor structure I in which the upper portion of the gate structure is wider than the outer sidewalls 240so of the gate spacers 240. The photoresist pattern PR in FIG. 6B is used to form the transistor structure II in which the upper portion of the gate structure has a same width as the outer sidewalls 240so of the gate spacers 240. The photoresist pattern PR in FIG. 6C is used to form the transistor structure III in which the upper portion of the gate structure is narrower than the outer sidewalls 240so of the gate spacers 240 but wider than the inner sidewalls 240si of the gate spacers 240.

In some embodiments of the transistor structure I, the upper portion 225u of the work function layer 225 is wider than the outer sidewalls 240so of the gate spacers 240. In some embodiments of the transistor structure I, the upper portion 220u of the filling conductor 220 is wider than the outer sidewalls 240so of the gate spacers 240.

In some embodiments of the transistor structure II, the upper portion 225u of the work function layer 225 is wider than the inner sidewalls 240si of the gate spacers 240. In some embodiments of the transistor structure II, the upper portion 220u of the filling conductor 220 is wider than the inner sidewalls 240si of the gate spacers 240.

In some embodiments of the transistor structure III, the upper portion 225u of the work function layer 225 is wider than the inner sidewalls 240si of the gate spacers 240. In some embodiments of the transistor structure III, the upper portion 220u of the filling conductor 220 is wider than the inner sidewalls 240si of the gate spacers 240.

In transistor structures I and II, 120 degrees≥D1≥90 degrees, and in transistor structure III, 120 degrees≥D10≥90 degrees. Maintaining the angles D1 and D10 at 120 degrees or less helps to avoid issues with adjacent structures, e.g., helps to avoid bridging with an adjacent contact such as a source/drain contact. Maintaining the angles D1 and D10 at 90 degrees or more helps with filling the filling conductor 220.

In transistor structures I, II, and III, the SAC layer 235 overlaps the gate spacers 240. In other words, an imaginary vertical line that passes through one of the gate spacers 240 also passes through the SAC layer 235.

In some embodiments, a method of fabricating a transistor includes: forming a dummy gate and gate spacers; forming an interlayer dielectric layer along sides of the gate spacers; forming a trench having a lower portion and an upper portion, the upper portion of the trench being wider than the lower portion of the trench, forming the trench including: removing a part of the gate spacers, and removing the dummy gate; forming a gate structure in the trench; and forming a self-aligned contact layer in the trench to contact an uppermost surface of the gate structure, wherein: the gate structure has a lower portion and an upper portion, the upper portion of the gate structure being in the upper portion of the trench, the lower portion of the gate structure being in the lower portion of the trench, and the upper portion of the gate structure being wider than the lower portion of the gate structure, a first one of the gate spacers has a first inner sidewall that faces a first side of the lower portion of the gate structure, and a second one of the gate spacers has a second inner sidewall that faces a second side of the lower portion of the gate structure, the first inner sidewall being spaced apart from the second inner sidewall by a first distance, and the self-aligned contact layer has a width that is greater than the first distance.

In some embodiments, forming the trench includes removing a part of the interlayer dielectric layer, sides of the upper portion of the trench are defined by sidewalls of the interlayer dielectric layer, and a minimum separation of the sidewalls is greater than a distance between outer sides of the gate spacers. In some embodiments, forming the trench includes performing at least one etch operation to remove the part of the interlayer dielectric layer, the part of the gate spacers, and the dummy gate, and the part of the interlayer dielectric layer is etched so that the upper portion of the trench is wider than the distance between the outer sides of the gate spacers. In some embodiments, forming the gate structure in the trench includes forming a gate dielectric layer in the trench and forming a gate conductive structure on the gate dielectric layer. In some embodiments, the self-aligned contact layer contacts the gate dielectric layer at first and second sides of the trench. In some embodiments, the self-aligned contact layer has a width equal to a width of the trench at an uppermost extent of the gate structure. In some embodiments, the method further includes forming an insulating layer on top of the gate structure, wherein the gate spacers have a height that is at least ⅓ of an overall distance from a bottom of the gate spacers to a top of the insulating layer. In some embodiments, forming the trench includes removing a part of the interlayer dielectric layer, sides of the upper portion of the trench are defined by sidewalls of the interlayer dielectric layer, and a minimum separation of the sidewalls is approximately the same as a distance between outer sides of the gate spacers. In some embodiments, forming the trench includes performing at least one etch operation to remove the part of the interlayer dielectric layer, the part of the gate spacers, and the dummy gate, and the part of the interlayer dielectric layer is etched so that the sidewalls of the interlayer dielectric layer in the upper portion of the trench are substantially aligned with the outer sides of the gate spacers. In some embodiments, the method further includes forming an insulating layer on top of the gate structure, wherein the gate spacers have a height that is at least ⅓ of an overall distance from a bottom of the gate spacers to a top of the insulating layer. In some embodiments, forming the trench includes making upper portions of gate spacers narrower, and sides of the upper portion of the trench are defined by sidewalls of the upper portions of the gate spacers. In some embodiments, forming the trench includes performing at least one etch operation to remove the part of the gate spacers and the dummy gate, and the gate spacers are etched so that the sidewalls of the upper portion of the trench are aligned with a point between inner sides and outer sides of the gate spacers. In some embodiments, the gate structure includes a filling conductor, the filling conductor is formed to have a lower portion and an upper portion, the upper portion of the filling conductor is in the upper portion of the trench, the lower portion of the filling conductor is in the lower portion of the trench, and the upper portion of the filling conductor is wider than the lower portion of the filling conductor. In some embodiments, forming the gate structure includes: forming a gate dielectric layer, the gate dielectric layer being formed to have a substantially uniform first thickness; forming a work function layer on the gate dielectric layer, the work function layer being formed to have a substantially uniform second thickness; and forming a filling conductor on the work function layer, the filling conductor being formed to fill a remaining part of the trench not occupied by the gate dielectric layer and the work function layer, and having a greater electrical conductivity than the work function layer.

In some embodiments, a transistor includes: a gate structure adjacent to a channel region of a substrate, the gate structure including a gate conductive structure and a gate dielectric layer at sides of the gate conductive structure; and a first gate spacer at a first side of the gate structure and a second gate spacer at a second side of the gate structure, wherein: a first portion of the gate dielectric layer extends above the first and second gate spacers, a second portion of the gate dielectric layer is between first portion of the gate dielectric layer and the substrate, the gate structure has a lower portion and an upper portion that is wider than the lower portion, the first gate spacer faces a first side of the lower portion of the gate structure, and the second gate spacer faces a second side of the lower portion of the gate structure, the first gate spacer being spaced apart in a first direction from the second gate spacer by a first distance, the upper portion of the gate structure has a width in the first direction that is greater than the first distance, the first portion of the gate dielectric layer includes an uppermost extent of the gate dielectric layer, and in the first portion of the gate dielectric layer, a width of a lateral spacing in the first direction of outer surfaces of the gate dielectric layer is greatest at the uppermost extent of the gate dielectric layer.

In some embodiments, the upper portion of the gate structure has a width that is greater than a distance between outer sidewalls of the first and second gate spacers. In some embodiments, the upper portion of the gate structure has a width that is approximately the same as a distance between outer sides of the first and second gate spacers. In some embodiments, the first and second gate spacers each have a wider bottom portion and a narrower top portion with a substantially horizontal step between the bottom portion and the top portion, and outer sidewalls of the upper portion of the gate structure contact inner sidewalls of the top portions of the first and second gate spacers. In some embodiments, the transistor further includes an insulating layer on top of the gate structure, wherein the first and second gate spacers have a height that is at least ⅓ of an overall distance from a bottom of the first and second gate spacers to a top of the insulating layer.

In some embodiments, a transistor includes: a gate structure including a gate conductive structure and a gate dielectric layer at first and second sides of the gate conductive structure; an insulating layer of a dielectric material extending across and contacting an uppermost surface of the gate structure and contacting an uppermost surface of the gate dielectric at the first and second sides of the gate conductive structure; a first gate spacer and a second gate spacer; and an interlayer dielectric layer along sides of the first and second gate spacers and along sides of the insulating layer, wherein: the gate structure has a lower portion and an upper portion, the lower portion being between the first and second gate spacers, and the upper portion extending from the lower portion to the insulating layer, and being wider than the lower portion, the first gate spacer has a first inner sidewall that faces a first side of the lower portion of the gate structure, and the second gate spacer has a second inner sidewall that faces a second side of the lower portion of the gate structure, the first inner sidewall being spaced apart from the second inner sidewall by a first distance, and the insulating layer has a width that is greater than the first distance.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of fabricating a transistor, the method comprising:
forming a dummy gate and gate spacers;
forming an interlayer dielectric layer along sides of the gate spacers;
forming a trench having a lower portion and an upper portion, the upper portion of the trench being wider than the lower portion of the trench, forming the trench including:
removing a part of the gate spacers, and
removing the dummy gate;
forming a gate structure in the trench; and
forming a self-aligned contact layer in the trench to contact an uppermost surface of the gate structure, wherein:
the gate structure has a lower portion and an upper portion, the upper portion of the gate structure being in the upper portion of the trench, the lower portion of the gate structure being in the lower portion of the trench, and the upper portion of the gate structure being wider than the lower portion of the gate structure,
a first one of the gate spacers has a first inner sidewall that faces a first side of the lower portion of the gate structure, and a second one of the gate spacers has a second inner sidewall that faces a second side of the lower portion of the gate structure, the first inner sidewall being spaced apart from the second inner sidewall by a first distance, and
the self-aligned contact layer has a width that is greater than the first distance.

2. The method of claim 1, wherein:
forming the trench includes removing a part of the interlayer dielectric layer,
sides of the upper portion of the trench are defined by sidewalls of the interlayer dielectric layer, and
a minimum separation of the sidewalls is greater than a distance between outer sides of the gate spacers.

3. The method of claim 2, wherein:
forming the trench includes performing at least one etch operation to remove the part of the interlayer dielectric layer, the part of the gate spacers, and the dummy gate, and
the part of the interlayer dielectric layer is etched so that the upper portion of the trench is wider than the distance between the outer sides of the gate spacers.

4. The method of claim 2, wherein forming the gate structure in the trench includes forming a gate dielectric layer in the trench and forming a gate conductive structure on the gate dielectric layer.

5. The method of claim 4, wherein the self-aligned contact layer contacts the gate dielectric layer at first and second sides of the trench.

6. The method of claim 5, wherein the self-aligned contact layer has a width equal to a width of the trench at an uppermost extent of the gate structure.

7. The method of claim 2, further comprising forming an insulating layer on top of the gate structure,
wherein the gate spacers have a height that is at least ⅓ of an overall distance from a bottom of the gate spacers to a top of the insulating layer.

8. The method of claim 1, wherein:
forming the trench includes removing a part of the interlayer dielectric layer,
sides of the upper portion of the trench are defined by sidewalls of the interlayer dielectric layer, and
a minimum separation of the sidewalls is approximately the same as a distance between outer sides of the gate spacers.

9. The method of claim 8, wherein:
forming the trench includes performing at least one etch operation to remove the part of the interlayer dielectric layer, the part of the gate spacers, and the dummy gate, and
the part of the interlayer dielectric layer is etched so that the sidewalls of the interlayer dielectric layer in the upper portion of the trench are substantially aligned with the outer sides of the gate spacers.

10. The method of claim 8, further comprising forming an insulating layer on top of the gate structure,
wherein the gate spacers have a height that is at least ⅓ of an overall distance from a bottom of the gate spacers to a top of the insulating layer.

11. The method of claim 1, wherein:
forming the trench includes making upper portions of gate spacers narrower, and
sides of the upper portion of the trench are defined by sidewalls of the upper portions of the gate spacers.

12. The method of claim 11, wherein:
forming the trench includes performing at least one etch operation to remove the part of the gate spacers and the dummy gate, and
the gate spacers are etched so that the sidewalls of the upper portion of the trench are aligned with a point between inner sides and outer sides of the gate spacers.

13. The method of claim 1, wherein:
the gate structure includes a filling conductor,
the filling conductor is formed to have a lower portion and an upper portion,
the upper portion of the filling conductor is in the upper portion of the trench,
the lower portion of the filling conductor is in the lower portion of the trench, and
the upper portion of the filling conductor is wider than the lower portion of the filling conductor.

14. The method of claim 1, wherein forming the gate structure includes:
forming a gate dielectric layer, the gate dielectric layer being formed to have a substantially uniform first thickness;
forming a work function layer on the gate dielectric layer, the work function layer being formed to have a substantially uniform second thickness; and
forming a filling conductor on the work function layer, the filling conductor being formed to fill a remaining part of the trench not occupied by the gate dielectric layer and the work function layer, and having a greater electrical conductivity than the work function layer.

15. A transistor comprising:
a gate structure adjacent to a channel region of a substrate, the gate structure including a gate conductive structure and a gate dielectric layer at sides of the gate conductive structure; and
a first gate spacer at a first side of the gate structure and a second gate spacer at a second side of the gate structure, wherein:
a first portion of the gate dielectric layer extends above the first and second gate spacers,
a second portion of the gate dielectric layer is between first portion of the gate dielectric layer and the substrate,
the gate structure has a lower portion and an upper portion that is wider than the lower portion,
the first gate spacer faces a first side of the lower portion of the gate structure, and the second gate spacer faces a second side of the lower portion of the gate structure, the first gate spacer being spaced apart in a first direction from the second gate spacer by a first distance,
the upper portion of the gate structure has a width in the first direction that is greater than the first distance,
the first portion of the gate dielectric layer includes an uppermost extent of the gate dielectric layer, and
in the first portion of the gate dielectric layer, a width of a lateral spacing in the first direction of outer surfaces of the gate dielectric layer is greatest at the uppermost extent of the gate dielectric layer.

16. The transistor of claim 15, wherein the upper portion of the gate structure has a width that is greater than a distance between outer sidewalls of the first and second gate spacers.

17. The transistor of claim 15, wherein the upper portion of the gate structure has a width that is approximately the same as a distance between outer sides of the first and second gate spacers.

18. The transistor of claim 15, wherein:
the first and second gate spacers each have a wider bottom portion and a narrower top portion with a substantially horizontal step between the bottom portion and the top portion, and
outer sidewalls of the upper portion of the gate structure contact inner sidewalls of the top portions of the first and second gate spacers.

19. The transistor of claim 15, further comprising an insulating layer on top of the gate structure,
wherein the first and second gate spacers have a height that is at least ⅓ of an overall distance from a bottom of the first and second gate spacers to a top of the insulating layer.

20. A transistor comprising:
a gate structure including a gate conductive structure and a gate dielectric layer at first and second sides of the gate conductive structure;
an insulating layer of a dielectric material extending across and contacting an uppermost surface of the gate structure and contacting an uppermost surface of the gate dielectric at the first and second sides of the gate conductive structure;
a first gate spacer and a second gate spacer; and
an interlayer dielectric layer along sides of the first and second gate spacers and along sides of the insulating layer, wherein:
the gate structure has a lower portion and an upper portion,
the lower portion being between the first and second gate spacers, and
the upper portion extending from the lower portion to the insulating layer, and being wider than the lower portion,
the first gate spacer has a first inner sidewall that faces a first side of the lower portion of the gate structure, and the second gate spacer has a second inner sidewall that faces a second side of the lower portion of the gate structure, the first inner sidewall being spaced apart from the second inner sidewall by a first distance, and
the insulating layer has a width that is greater than the first distance.
